(19) United States
(12) Patent Application Publication
(10) Pub. No.: US 2024/0087969 A1
(43) Pub. Date: Mar. 14, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke KAMIYA, Nonoichi Ishikawa (JP); Shinya OZAWA, Kanazawa Ishikawa (JP); Shuji EGUMA, Hakusan Ishikawa (JP); Masaru IZUMISAWA, Kanazawa Ishikawa (JP)

(21) Appl. No.: 18/179,669

(22) Filed: Mar. 7, 2023

(30) Foreign Application Priority Data
Sep. 14, 2022 (JP) 2022-146063

(51) Int. Cl. H01L 23/13; H01L 23/00; H01L 23/492

(52) U.S. Cl. CPC H01L 23/13; H01L 23/492; H01L 24/32; H01L 24/40; H01L 24/73; H01L 2224/32245; H01L 2224/40175; H01L 2224/73263; H01L 2924/13091; H01L 2924/1515

(57) ABSTRACT

A semiconductor device includes a base member and a semiconductor chip. The base member includes a first surface, a second surface opposite to the first surface, and a protrusion at the second surface side. The semiconductor chip being mounted on the second surface of the base member. The semiconductor chip includes first and second electrodes, a control pad, and a semiconductor part. The first electrode is provided on a back surface of the semiconductor part. The second electrode and the control pad are provided on a front surface of the semiconductor part. The semiconductor chip includes a space between the second electrode and the control pad at the front surface side of the semiconductor part. The semiconductor chip is mounted so that the space between the second electrode and the control pad overlaps the protrusion of the base member.

### CROSS-REFERENCE TO RELATED APPLICATIONS

This application is based upon and claims the benefit of priority from Japanese Patent Application No. 2022-146063, filed on Sep. 14, 2022; the entire contents of which are incorporated herein by reference.

### FIELD

Embodiments relate to a semiconductor device.

### BACKGROUND

A semiconductor device is required to have a wide safe operating area (SOA).

### BRIEF DESCRIPTION OF THE DRAWINGS

FIGS. 1A and 1B are schematic views showing a semiconductor device according to an embodiment;

FIG. 2 is a schematic cross-sectional view showing the semiconductor device according to the embodiment;

FIG. 3 is a schematic plan view showing the semiconductor chip according to the embodiment;

FIGS. 4A to 4C are schematic plan views illustrating the base member according to the embodiment;

FIGS. 5A and 5B are schematic views showing a semiconductor device according to a modification of the embodiment;

FIGS. 6A and 6B are schematic views showing a semiconductor device according to another modification of the embodiment;

FIG. 7 is a schematic plan view showing a base member according to a modification of the embodiment; and

FIGS. 8A and 8B are schematic cross-sectional view showing a semiconductor device according to a comparative example.

### DETAILED DESCRIPTION

According to one embodiment, a semiconductor device includes a base member, a semiconductor chip, and a first conductive member. The base member includes a first surface, a second surface, and a protrusion, the second surface being at a side opposite to the first surface. The protrusion is provided at the second surface side, and protrudes in a first direction perpendicular to the second surface. The semiconductor chip being mounted on the second surface of the base member via a first connection member. The semiconductor chip includes a first electrode, a second electrode, a control pad, and a semiconductor part. The first electrode is provided on a back surface of the semiconductor part. The first connection member is connected to the first electrode. The second electrode and the control pad are provided on a front surface of the semiconductor part, the front surface being at a side opposite to the back surface of the semiconductor part. The control pad is apart from the second electrode. The semiconductor part is positioned between the first electrode and the second electrode and between the first electrode and the control pad. The first conductive member is bonded on the second electrode of the semiconductor chip via a second connection member. The semiconductor chip includes a space between the second electrode and the control pad at the front surface side of the semiconductor part. The semiconductor chip is mounted so that the protrusion of the base member and the space between the second electrode and the control pad overlap in the first direction. The space between the second electrode and the control pad includes a first portion and a second portion. The first portion extends along the front surface of the semiconductor part in a second direction; and the second portion extends along the front surface of the semiconductor part in a third direction crossing the second direction. The first portion of the space has a first long-side length in the second direction; and the second portion of the space has a second long-side length in the third direction. The protrusion of the base member has a first length in the second direction and a second length in the third direction. The first length of the protrusion is equal to or greater than the first long-side length of the first portion of the space between the second electrode and the control pad. The second length of the protrusion is equal to or greater than the second long-side length of the second portion of the space between the second electrode and the control pad.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

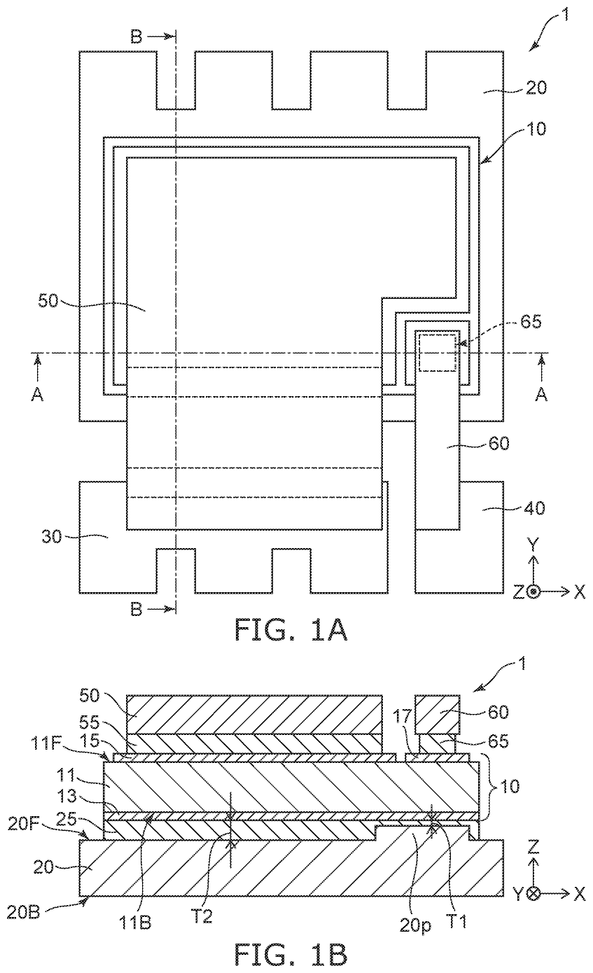

FIGS. 1A and 1B are schematic views showing a semiconductor device 1 according to an embodiment. FIG. 1A is a plan view showing the upper surface of the semiconductor device 1. FIG. 1B is a cross-sectional view along line A-A shown in FIG. 1A.

The semiconductor device 1 is, for example, a MOS transistor for power control. The semiconductor device 1 includes, for example, a semiconductor chip 10, a base member 20, a first terminal 30, a second terminal 40, a first conductive member 50, and a second conductive member 60.

As shown in FIG. 1A, the semiconductor chip 10 is mounted on the base member 20. The first terminal 30 and the second terminal 40 are apart from the base member 20, for example, in the X-Y plane. The first terminal 30 and the second terminal 40 are apart from each other.

The first terminal 30 is electrically connected to the semiconductor chip 10 via the first conductive member 50. The first conductive member 50 is, for example, a plate-shaped metal connector. The second terminal 40 is electrically connected to the semiconductor chip 10 via the second conductive member 60. The second conductive member 60 is, for example, a plate-shaped metal connector. Alternatively, the second conductive member 60 may be, for example, a metal wire.

As shown in FIG. 1B, the semiconductor chip 10 includes a semiconductor part 11, a first electrode 13, a second electrode 15, and a control pad 17. The semiconductor part 11 is, for example, silicon carbide (SiC). The semiconductor part 11 is provided between the first electrode 13 and the second electrode 15, and between the first electrode 13 and the control pad 17. The first electrode 13 is provided on a back surface 11B of the semiconductor part 11. The second electrode 15 and the control pad 17 are provided on a front surface 11F of the semiconductor part 11 and are apart from each other. The control pad 17 is provided on the semiconductor part 11 with an insulating film (not illustrated) interposed, and is electrically insulated from the semiconductor part 11.

The first electrode 13 is, for example, the drain electrode of the MOS transistor. The second electrode 15 is, for example, the source electrode of the MOS transistor. The control pad 17 is electrically connected to, for example, the gate electrode (not illustrated) of the MOS transistor. The gate electrode, for example, is provided between the semiconductor part 11 and the second electrode 15.

The base member 20 includes a back surface 20B (a first surface) and a front surface 20F (a second surface). The front surface 20F is positioned at the side opposite to the back surface 20B. The semiconductor chip 10 is mounted on the front surface 20F of the base member 20 via a first connection member 25. The first connection member 25 is, for example, a solder material. The first electrode 13 of the semiconductor chip 10 is connected to the first connection member 25. The semiconductor chip 10 is electrically connected to the base member 20 via the first connection member 25.

The first conductive member 50 is connected to the second electrode 15 via a second connection member 55. The second connection member 55 is, for example, a solder material. The first conductive member 50 is electrically connected to the second electrode 15 via the second connection member 55.

The second conductive member 60 is connected to the control pad 17 via a third connection member 65. The third connection member 65 is, for example, a solder material. The second conductive member 60 is electrically connected to the control pad 17 via the third connection member 65. When a metal wire is used as the second conductive member 60, the second conductive member 60 is directly bonded on the control pad 17.

As shown in FIG. 1B, the base member 20 includes a protrusion 20p that is partially provided in the front surface 20F side. The semiconductor chip 10 is mounted so that the space between the second electrode 15 and the control pad 17 in the X-Y plane overlaps the protrusion 20p in, for example, a Z-direction perpendicular to the front surface 20F of the base member 20. Also, the space between the second connection member 55 and the third connection member 65 in the X-Y plane preferably overlaps the protrusion 20p of the base member 20 in the Z-direction.

In the semiconductor device 1, the first connection member 25 is provided with a thickness T1 in the Z-direction between the semiconductor chip 10 and the protrusion 20p of the base member 20 and a thickness T2 in the Z-direction between the base member 20 and the second connection member 55. The thickness T1 is less than the thickness T2. Thereby, even when voids are generated in the first connection member 25 during the process of mounting the semiconductor chip 10 on the base member 20, it is possible to prevent a void positioned between the semiconductor chip 10 and the protrusion 20p. Although, in the reflow process of mounting the semiconductor chip 10 on the base member 20, for example, small voids may collect to form a large void, such voids do not form between the semiconductor chip 10 and the protrusion 20p and do not move into a position between the semiconductor chip 10 and the protrusion 20p.

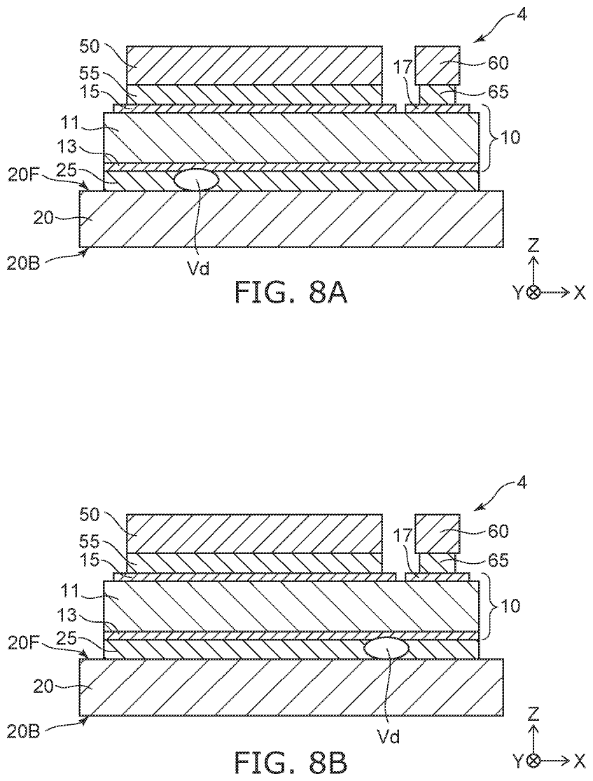

On the other hand, in a semiconductor device 4 according to a comparative example shown in FIGS. 8A and 8B, the protrusion 20p is not provided at the front surface 20F side of the base member 20. The semiconductor chip 10 is mounted on a flat front surface 20F via the first connection member 25.

There may be a case where the first connection member 25 includes a void Vd, for example, when the semiconductor chip 10 has a large size in the X-direction and the Y-direction. Such a void Vd partially inhibits the thermal conduction from the semiconductor chip 10 to the base member 20.

As shown in FIG. 8A, when the void Vd occurs between the base member 20 and the first conductive member 50, the thermal conduction from the semiconductor chip 10 to the base member 20 is partially inhibited, but the thermal conduction path from the semiconductor chip 10 to the first conductive member 50 via the second connection member 55 is maintained. Therefore, it is possible inside the semiconductor chip 10 to suppress a temperature rise.

As shown in FIG. 8B, when the void Vd is positioned below the space between the first conductive member 50 and the second conductive member 60, however, the thermal conduction from the semiconductor chip 10 to the base member 20 is partially inhibited, and an upward thermal conduction path is lost. That is, the semiconductor chip 10 includes a region at which the heat dissipation is limited, and the temperature distribution in the semiconductor chip 10 becomes nonuniform. In other words, when the void Vd is positioned below the space between the first conductive member 50 and the second conductive member 60, the semiconductor chip 10 includes a region at which the temperature rises and the electrical resistance locally decreases. Therefore, current easily concentrates at the vicinity of the void Vd; and the temperature rises more. As a result, there may be a case where the current is acceleratingly concentrated, causing element breakdown. That is, in the semiconductor device 4, there is a risk that the safe operating area (SOA) may become narrow.

In contrast, in the semiconductor device 1 according to the embodiment, the protrusion 20p of the base member 20 is provided below the space between the first conductive member 50 and the second conductive member 60. Thereby, it is possible to prevent the void Vd from being positioned below the space between the first conductive member 50 and the second conductive member 60. Accordingly, the wide SOA is maintained in the semiconductor device 1.

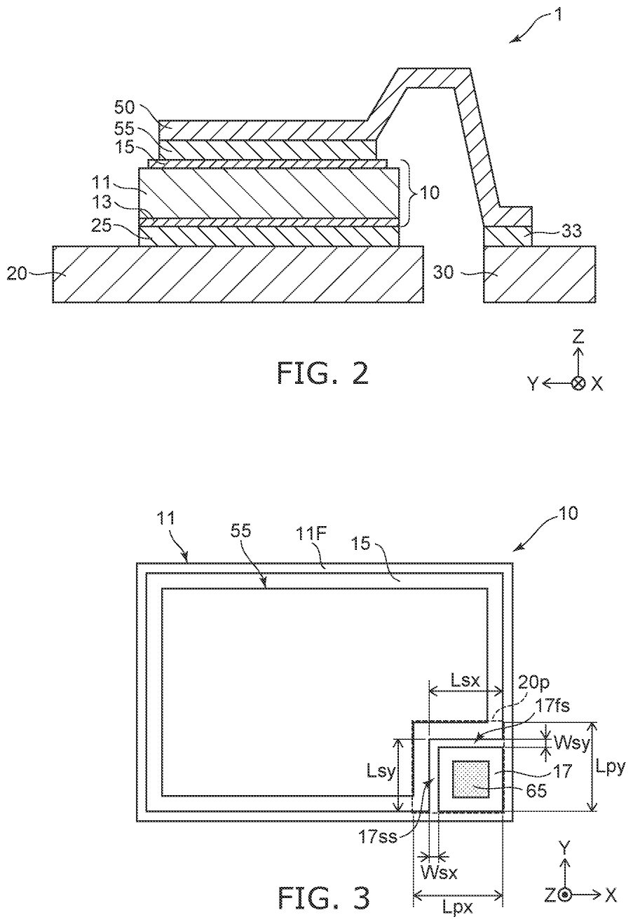

FIG. 2 is a schematic cross-sectional view showing the semiconductor device 1 according to the embodiment. FIG. 2 is a schematic view showing a cross section along line B-B shown in FIG. 1A.

As shown in FIG. 2, the first conductive member 50 is, for example, a bent plate-shaped connector. By providing the first conductive member 50, large current flows from the second electrode 15 of the semiconductor chip 10 to the first terminal 30. The heat of the semiconductor chip 10 is dissipated via the first connection member 55 and the first conductive member 50.

The first conductive member 50 is connected to the second electrode 15 of the semiconductor chip 10 via the second connection member 55. Also, the first conductive member 50 is connected to the first terminal 30 via a fourth connection member 33. The fourth connection member 33 is, for example, a solder material. The first conductive member 50 is connected to the semiconductor chip 10 preferably at the entire surface of the second electrode 15 other than the outer edge of the second electrode 15 (see FIG. 1A). Thereby, the semiconductor chip 10 can be operated with the large current, and the heat that is generated in the semiconductor part 11 can be efficiently dissipated.

FIG. 3 is a schematic plan view showing the semiconductor chip 10 according to the embodiment. FIG. 3 is a plan view showing the front surface 11F side of the semiconductor part 11. FIG. 3 shows the layout of the second electrode 15, the control pad 17, the second connection member 55, and the third connection member 65.

As shown in FIG. 3, the second electrode 15 and the control pad 17 are provided on the front surface 11F of the semiconductor part 11. The front surface 11F of the semiconductor part 11 is, for example, quadrilateral; and the control pad is provided at one corner of the quadrilateral. The second electrode 15 covers the greater part of the front surface 11F side of the semiconductor part 11 other than the outer edge of the semiconductor part 11 and the corner of the semiconductor part 11 at which the control pad 17 is provided. The second connection member 55 covers preferably the entire surface of the second electrode 15 other than the outer edge of the second electrode 15.

The control pad 17 is apart from the second electrode 15. The space between the second electrode 15 and the control pad 17 includes, for example, a first portion 17fs extending in the X-direction, and a second portion 17ss extending in the Y-direction. The first portion 17fs has a space-length Lsx in the X-direction and a short-side width Wsy in the Y-direction. The second portion 17ss has a long-side length Lsy in the Y-direction and a short-side width Wsx in the X-direction.

As shown by the broken line in FIG. 3, the protrusion 20p of the base member 20 has, for example, a quadrilateral shape when viewed in a plan view parallel to the front surface 11F of the semiconductor part 11. The protrusion 20p of the base member 20 has, for example, a length Lpx in the X-direction and a length Lpy in the Y-direction. The protrusion 20p is formed so that the length Lpx in the X-direction is preferably equal to or greater than the long-side length Lsx in the X-direction of the space between the second electrode 15 and the control pad 17. Also, the protrusion 20p is formed so that the length Lpy in the Y-direction is preferably equal to or greater than the long-side length Lsy in the Y-direction of the space between the second electrode 15 and the control pad 17. In the example, the protrusion 20p also extends below the third connection member 65.

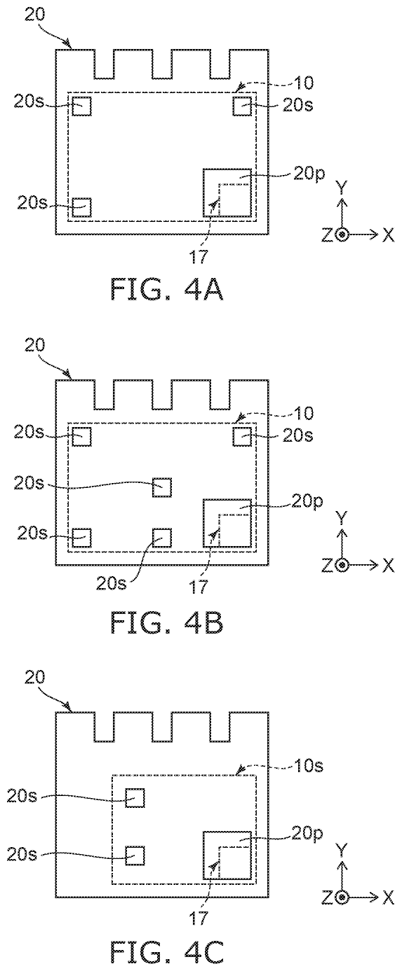

FIGS. 4A to 4C are schematic plan views illustrating the base member 20 according to the embodiment. The broken lines shown in the drawings show the outer edge of the semiconductor chip 10 and the outer edge of the control pad 17.

As shown in FIG. 4A, the protrusion 20p of the base member 20 preferably overlaps the control pad 17 and extends toward the center of the semiconductor chip 10 in the plan view. Thereby, the protrusion 20p can also overlap the space between the control pad 17 and the second connection member 55 (see FIG. 3).

The base member 20 may further include another protrusion 20s. The protrusion 20s has a size smaller in the X-direction and the Y-direction than the size of the protrusion 20p. The protrusions 20s are provided below, for example, three corners of the four corners of the semiconductor chip 10 other than the corner positioned on the protrusion 20p. Thereby, the semiconductor chip 10 can be mounted without tilting on the front surface 20F of the base member 20 (see FIG. 1B).

When the semiconductor chip 10 is mounted so that tilting with respect to the front surface 20F of the base member 20, it is difficult to connect the first conductive member 50 on the semiconductor chip 10. Also, the escape rout of air remaining between the semiconductor chip 10 and the first connection member 25 is constrained, and the void Vd easily occurs in the first connection member 25. Such a defect can be avoided by providing the protrusions 20s.

As shown in FIG. 4B, in addition to the protrusions 20s positioned below the three corners of the semiconductor chip 10, other protrusions 20s may be provided such that another protrusion 20s is provided below the center of the semiconductor chip 10; and yet another protrusion 20s and the protrusion 20p are arranged in the X-direction. Thereby, even when a semiconductor chip 10s that is smaller than the semiconductor chip 10 is provided (see FIG. 4C), the semiconductor chip 10s also can be held on the protrusion 20p and the protrusions 20s so that not tilting with respect to the front surface 20F of the base member 20.

As shown in FIG. 4C, two protrusions 20s that are arranged in the Y-direction may be provided at the center area in the X-direction of the base member 20. Thereby, the semiconductor chip 10s that is smaller than the semiconductor chip 10 can be held without tilting by the protrusion 20p and the protrusions 20s. Thus, by providing the protrusions 20s, it is possible to prevent the semiconductor chip 10 from tilting. The air that remains between the semiconductor chip 10 and the first connection member 25 can easily escape toward outside of the semiconductor chip 10, thereby preventing the void Vd.

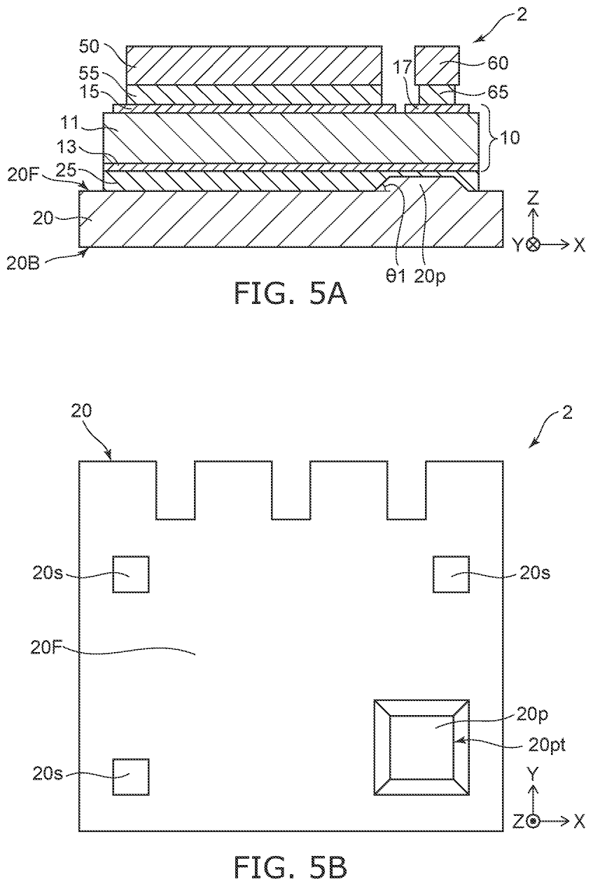

FIGS. 5A and 5B are schematic views showing a semiconductor device 2 according to a modification of the embodiment. FIG. 5A is a cross-sectional view along line A-A shown in FIG. 1A. FIG. 5B is a plan view showing the front surface 20F side of the base member 20.

As shown in FIG. 5A, the protrusion 20p includes a side surface that is oblique to the front surface 20F of the base member 20. An incline angle θ1 of the side surface of the protrusion 20p is, for example, 45°.

As shown in FIG. 5B, the protrusion 20p has, for example, two side surfaces in the X-direction and another two side surfaces in Y-direction that are oblique to the front surface 20F of the base member 20. The protrusion 20p also has an upper surface 20pt with a surface area narrower than an area surrounded with the boundary between the protrusion 20p and the front surface 20F of the base member 20.

By providing such a protrusion 20p, the first connection member 25 can move away from the protrusion 20p while mounting the semiconductor chip 10. Thereby, the void Vd can move away from the region beneath the space between the second connection member 55 and the third connection member 65 (see FIG. 8B).

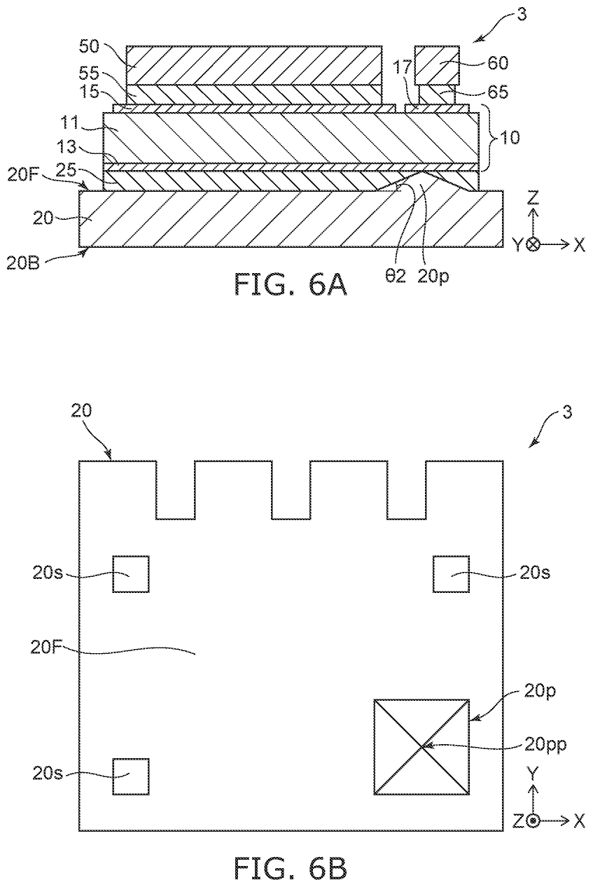

FIGS. 6A and 6B are schematic views showing a semiconductor device 3 according to another modification of the embodiment. FIG. 6A is a cross-sectional view along line A-A shown in FIG. 1A. FIG. 6B is a plan view showing the front surface 20F side of the base member 20.

As shown in FIG. 6A, the protrusion 20p includes side surfaces oblique to the front surface 20F of the base member 20. An incline angle θ2 of the side surfaces of the protrusion 20p is, for example, 30°.

As shown in FIG. 6B, the protrusion 20p has, for example, a quadrilateral pyramid shape. The protrusion 20p has, for example, an apex 20pp contacting the first electrode 13 of the semiconductor chip 10. Also, by such a protrusion 20p, the first connection member 25 can move away from the protrusion 20p while mounting the semiconductor chip 10. Thereby, the void Vd can move away from the region beneath the space between the second connection member 55 and the third connection member 65 (see FIG. 8B).

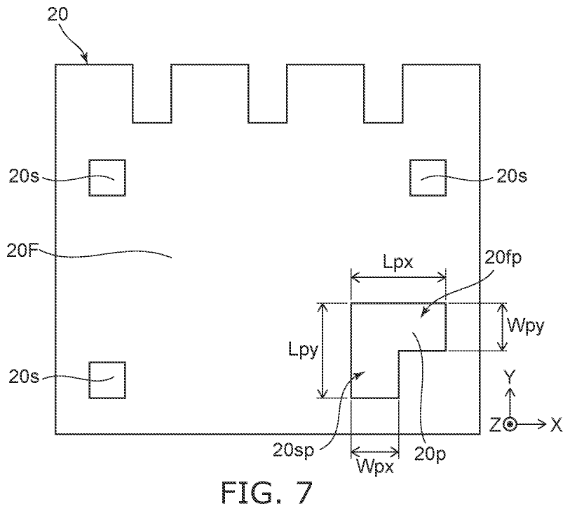

FIG. 7 is a schematic plan view showing a base member according to a modification of the embodiment. FIG. 7 is a schematic plan view showing the front surface 20F side of the base member 20.

As shown in FIG. 7, the protrusion 20p of the base member 20 may have, for example, an L-shaped planar shape in the plan view parallel to the front surface 20F. The protrusion 20p includes a first portion 20fp extending in the X-direction, and a second portion 20sp extending in the Y-direction. In the protrusion 20p, the length Lpx in the X-direction of the first portion 20fp is equal to or greater than the long-side length Lsx in the X-direction of the first portion 17fs of the space between the second electrode 15 and the control pad 17 (see FIG. 3). Also, in the protrusion 20p, the length Lpy in the Y-direction of the second portion 20sp is equal to or greater than the long-side length Lsy in the Y-direction of the second portion 17ss of the space between the second electrode 15 and the control pad 17 (see FIG. 3).

The second portion 20sp of the protrusion 20p has a width Wpx in the X-direction that is greater than the short-side width Wsx in the X-direction of the second portion 17ss of the space between the second electrode 15 and the control pad 17. The first portion 20fp of the protrusion 20p has a width Wpy in the Y-direction that is greater than the short-side width Wsy in the Y-direction of the first portion 17fs of the space between the second electrode 15 and the control pad 17.

Such a protrusion 20p has the planer shape that matches the space between the second connection member 55 and the third connection member 65 (see FIG. 3). The semiconductor chip 10 is mounted so that the protrusion 20p overlaps the space between the second connection member 55 and the third connection member 65 in the Z-direction. In other words, the protrusion 20p is provided below the space at which the second connection member 55 and the third connection member 65 are not provided on the semiconductor chip 10.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and overview of the invention.

What is claimed is:

1. A semiconductor device, comprising:
a base member including a first surface, a second surface, and a protrusion, the second surface being at a side opposite to the first surface, the protrusion being provided at the second surface side, the protrusion protruding in a first direction perpendicular to the second surface;
a semiconductor chip mounted on the second surface of the base member via a first connection member, the semiconductor chip including a first electrode, a second electrode, a control pad, and a semiconductor part, the first electrode being provided on a back surface of the semiconductor part, the first connection member being connected to the first electrode, the second electrode and the control pad being provided on a front surface of the semiconductor part, the front surface being at a side opposite to the back surface of the semiconductor part, the control pad being apart from the second electrode, the semiconductor part being positioned between the first electrode and the second electrode and between the first electrode and the control pad; and
a first conductive member bonded on the second electrode of the semiconductor chip via a second connection member,
the semiconductor chip including a space between the second electrode and the control pad at the front surface side of the semiconductor part, the semiconductor chip being mounted so that the protrusion of the base member and the space between the second electrode and the control pad overlap in the first direction,
the space between the second electrode and the control pad including a first portion and a second portion, the first portion extending along the front surface of the semiconductor part in a second direction, the second portion extending along the front surface of the semiconductor part in a third direction crossing the second direction, the first portion of the space having a first long-side length in the second direction, the second portion of the space having a second long-side length in the third direction,
the protrusion of the base member having a first length in the second direction and a second length in the third direction, the first length of the protrusion being equal to or greater than the first long-side length of the first portion of the space between the second electrode and the control pad, the second length of the protrusion being equal to or greater than the second long-side length of the second portion of the space between the second electrode and the control pad.

2. The device according to claim 1, wherein
the first portion of the space between the second electrode and the control pad has a first short-side width in the third direction, the first short-side width being less than the second long-side length in the third direction of the second portion of the space, and
the second portion of the space has a second short-side width in the second direction, the second short-side width being less than the first long-side length in the second direction of the first portion of the space.

3. The device according to claim 2, wherein
the control pad of the semiconductor chip overlaps the protrusion of the base member in the first direction.

4. The device according to claim 2, wherein
the second electrode of the semiconductor chip includes an inner portion and an outer edge portion, the outer edge portion extending outward from the inner portion between the semiconductor part and the second connection member, the outer edge portion extending along the space between the second electrode and the control pad, and
the outer edge portion of the second electrode overlaps the protrusion of the base member in the first direction.

5. The device according to claim 1, wherein
the semiconductor chip has a quadrilateral shape including four corners facing the base member via the first connection member, and
the control pad is provided at one of the four corners.

6. The device according to claim 5, wherein
the base member further includes a second protrusion facing the semiconductor chip via the first connection member at another one of the four corners.

7. The device according to claim 5, wherein
the base member further includes second protrusions facing the semiconductor chip, and the semiconductor chip includes three corners facing the second protrusions, respectively.

8. The device according to claim 6, wherein
the protrusion of the base member includes a first surface facing the semiconductor chip via the first connection member,
the second protrusion of the base member includes a second surface facing the semiconductor chip via the first connection member, and
a first surface area of the first surface is greater than a second surface area of the second surface.

9. The device according to claim 1, wherein
the first connection member has a first thickness in the first direction and a second thickness in the first direction, the first thickness being defined between the first electrode and a portion other than the protrusion of the base member, the second thickness being defined between the first electrode and the protrusion of the base member, and
the first thickness is greater than the second thickness.

10. The device according to claim 1, wherein
the protrusion of the base member includes a side surface oblique to the second surface.

11. The device according to claim 10, wherein
the protrusion of the base member includes a top surface facing the semiconductor chip via the first connection member, and
the top surface of the protrusion has a first width in the second direction and a second width in the third direction, the first width being less than the first length in the second direction of the protrusion, the second width being less than the second length in the third direction of the protrusion.

12. The device according to claim 10, wherein
the protrusion of the base member has a quadrilateral pyramid shape including an apex contacting the first electrode.

13. The device according to claim 1, further comprising:
a second conductive member bonded on the control pad of the semiconductor chip via a third connection member,
the protrusion of the base member overlapping a space between the second connection member and the third connection member in the first direction.

14. The device according to claim 13, wherein
the protrusion of the base member has a planar shape same as the space between the second connection member and the third connection member in a plan view parallel to the second surface.
